(19) United States
(12) Patent Application Publication
(10) Pub. No.: US 2005/0046308 A1
(43) Pub. Date: Mar. 3, 2005

(54) Control device for vibration type actuator

(76) Inventor: Takayuki Endo, Tochigi (JP)

Correspondence Address: MORGAN & FINNEGAN, L.L.P., 3 WORLD FINANCIAL CENTER, NEW YORK, NY, 10281-2101, US

(21) Appl. No.: 10/930,238

(22) Filed: Aug. 31, 2004

(30) Foreign Application Priority Data
Sep. 1, 2003 (JP) 2003-309207

(51) Int. Cl. H01L 41/09

(52) U.S. Cl. 310/317

(57) ABSTRACT

A control device is disclosed, with which generation of a squeaking noise from a vibration type actuator can be suppressed without stopping the driving process, when the vibration type actuator cannot be started due to an external force or the like. The control device includes a controller controlling a frequency of a periodic signal applied to an electro-mechanical energy conversion element between a first frequency and a second frequency which is lower than the first frequency, and a detector detecting driving of the vibration type actuator. In a case where driving of the vibration type actuator is not detected by the detector even when the frequency of the periodic signal is set to the second frequency, the controller continuously changes the frequency of the periodic signal between the second frequency and a third frequency that is lower than the first frequency until driving of the vibration type actuator is detected.

### BACKGROUND OF THE INVENTION

1. Field of the Invention

The present invention relates to the control of vibration type actuators used as driving sources of various kinds of apparatuses, such as cameras, lens apparatuses and image forming apparatuses.

2. Description of the Related Art

Vibration type actuators (also referred to as “vibration type motors” below) are non-electromagnetic actuators in which electro-mechanic energy conversion elements, such as piezoelectric elements, are attached to a vibration member corresponding to the stator of an electromotor, a traveling wave vibration is generated at the surface of the vibration member by applying to the electro-mechanic energy conversion elements a plurality of periodic signals, such as alternating voltages or pulse signals with different phases, driving the rotor (or movable member) which is pressed against the surface of the vibration member.

In order to rotate a vibration type motor smoothly and drive it with consistent speed even under somewhat varying environmental conditions, a method is known by which, beginning with a high frequency, the driving frequency is gradually reduced when starting the vibration type motor, and after the motor has been started, speed control and phase control are carried out in order to bring the driving speed of the motor close to the desired driving speed.

For speed control, the driving speed of the motor is detected at a certain period, the detected driving speed is compared with a desired driving speed, and in accordance with the difference, the frequency of the periodic signals (driving frequency) is increased or decreased.

For phase control, there is a method of detecting the phase difference between the periodic voltage applied to an electro-mechanical energy conversion element used for driving the motor and the periodic voltage obtained from an electro-mechanical energy conversion element used as a sensor, and controlling the driving frequency in accordance with the detected phase difference.

Speed control is carried out in order to not only setting the driving speed of the motor reliably to a high speed, but also smoothly stopping the motor. And phase control means that the driving frequency is controlled such that the driving frequency is not further lowered from the vicinity of the resonance frequency that is attained at the maximum speed of the motor, and is carried out in order to avoid the sudden stopping of the vibration type motor. A method that is often used is to gradually lower the frequency by a predetermined frequency amount at constant time intervals during start-up of the motor, to perform phase control and speed control after the motor has started, and to perform only speed control when the motor is stopped.

However, in this conventional method for controlling a vibration type motor, if the motor does not start because the movement of the member that is to be driven by the motor is impeded by an external force or the like during start-up of the motor, then the motor driving process is terminated at that point, or the driving process is terminated after scanning from a frequency higher than the driving frequency to a lower frequency, or a control as proposed in Japanese Patent Application Laid-Open No. H6 (1994)-6990 is performed.

In the control method of Japanese Patent Application Laid-Open No. H6 (1994)-6990, if the motor cannot be started even though a scan of the driving frequency has been performed, then the driving process is not terminated right away, but phase control is performed while performing once again a driving frequency scan from the maximum frequency that can be set, and it is ensured that the driving frequency does not become lower than the resonance frequency.

However, if phase control is performed and it is ensured that the frequency does not become lower than the resonance frequency while the vibration type motor cannot be started, as in the control method proposed in Japanese Patent Application Laid-Open No. H6 (1994)-6990, then the vibration state of the motor may become instable and so-called squeaking (abnormal noise) may be generated from the motor.

Squeaking of the motor similarly occurred also when impeding movement of the member, which is driven by the motor, by an external force, or when attempting to drive the motor further while the member to be driven abuts against the end of its movable range (mechanical end).

### SUMMARY OF THE INVENTION

It is one object of the present invention to provide a control device with which generation of a squeaking noise from the motor can be suppressed without stopping the driving process, when a vibration type actuator cannot be started due to an external force or the like.

According to one aspect of the present invention, a control device for a vibration type actuator comprises a controller controlling a frequency of a periodic signal applied to an electro-mechanical energy conversion element between a first frequency and a second frequency which is lower than the first frequency, and a detector detecting driving of the vibration type actuator. In a case where driving of the vibration type actuator is not detected by the detector even when the frequency of the periodic signal is set to the second frequency, the controller continuously changes the frequency of the periodic signal between the second frequency and a third frequency that is lower than the first frequency until driving of the vibration type actuator is detected.

According to another aspect of the present invention, a control method or control program for controlling a vibration type actuator comprises a first step of controlling a frequency of a periodic signal applied to an electro-mechanical conversion element between a first frequency and a second frequency which is lower than the first frequency, a second step of detecting driving of the vibration type actuator, and a third step of continuously changing the frequency of the periodic signal between the second frequency and a third frequency that is lower than the first frequency until driving of the vibration type actuator is detected, in a case where driving of the vibration type actuator is not detected even when the frequency of the periodic signal is set to the second frequency.

According to yet another aspect of the present invention, a control device for a vibration type actuator comprises a controller controlling a frequency of a periodic signal applied to an electro-mechanical conversion element between a first frequency and a second frequency which is lower than the first frequency, and a detector detecting driving of the vibration type actuator. In a case where driving of the vibration type actuator is not detected by the detector even when the frequency of the periodic signal is set to a third frequency between the first and the second frequency, the controller repeatedly changes the frequency of the periodic signal between the third frequency and a fourth frequency.

According to another aspect of the present invention, a control method or control program for controlling a vibration type actuator comprises a first step of controlling a frequency of the periodic signal between a first frequency and a second frequency which is lower than the first frequency, a second step of detecting driving of the vibration type actuator, and a third step of, in a case where driving of the vibration type actuator is not detected even when the frequency of the periodic signal is set to a third frequency between the first and the second frequency, repeatedly changing the frequency of the periodic signal between the third frequency and a fourth frequency.

These and further objects and features of the control device, control method and control program for a vibration type actuator according to the present invention will become apparent from the following detailed description of preferred embodiments thereof taken in conjunction with the accompanying drawings.

### BRIEF DESCRIPTION OF THE DRAWINGS

FIG. 1 is a block diagram showing the structure of a camera system according to Embodiment 1 of the present invention.

FIG. 2 is a timing chart illustrating the frequency adjustment method in Embodiment 1.

FIG. 3 is a flowchart showing the operation of the camera system according to Embodiment 1.

FIG. 4 is a flowchart showing the operation of the camera system according to Embodiment 1.

FIG. 5 is a flowchart showing the operation of the camera system according to Embodiment 1.

FIG. 6 is a flowchart showing the operation of the camera system according to Embodiment 1.

FIG. 7 is a flowchart showing the operation of the camera system according to Embodiment 1.

FIG. 8 is a flowchart showing the operation of the camera system according to Embodiment 1.

FIG. 9 is a flowchart showing the operation of a camera system according to Embodiment 2.

FIG. 10 is a timing chart illustrating the frequency adjustment method in Embodiment 2.

FIG. 11A is a diagram showing the arrangement of the piezoelectric elements of the vibration type motor in the embodiments of the present invention.

FIG. 11B is a graph showing the characteristics of a vibration type motor.

FIG. 12 is a block diagram showing the overall structure of a camera system according to the embodiments.

FIG. 13 is a timing chart showing a modified example of a frequency adjustment method according to the embodiments of the present invention.

### DETAILED DESCRIPTION OF THE PREFERRED EMBODIMENTS

The following is a detailed explanation of embodiments of the present invention, with reference to the accompanying drawings.

Embodiment 1

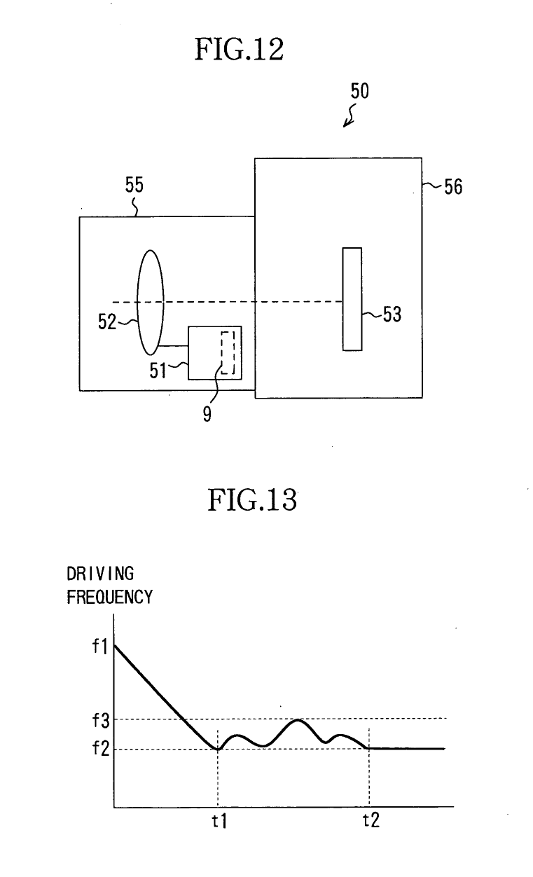

FIG. 12 shows the overall structure of a camera system, which is an apparatus provided with a vibration type motor (vibration type actuator) according to Embodiment 1 of the present invention as a driving source. This camera system 50 is made of a digital camera section 56 including an image-pickup element 53, such as a CCD sensor or a CMOS sensor, and a lens section 55 provided integrally with the digital camera section 56. It should be noted that the present invention can also be applied to camera systems which take images using photosensitive film instead of the image-pickup element 53. The present invention can also be applied to camera systems in which the digital camera section 56 and the lens section 55 can be removably attached to each other via a mount mechanism (not shown in the drawings).

In FIG. 12, reference numeral 9 denotes a vibration type motor, and reference numeral 52 denotes a focusing lens (driven member) which constitutes a portion of an image-taking optical system. The driving force of the vibration type motor 9 is transmitted via a focus driving mechanism 51 to the focusing lens 52, and moves the focusing lens 52 in the optical axis direction, which is indicated by the dotted line in the figure. When the focusing lens 52 has been driven to the in-focus position, an object image is photoelectrically converted by the image-pickup element 53, and the object image is recorded as electronic image information onto a recording medium (semiconductor memory, magnetic disk, optical disk or the like) not shown in the drawings. Moreover, it is also possible to perform the focusing control for moving the focusing lens 52 to the in-focus position by the phase difference detection method or contrast detection (TV-AF) method based on the output signal from the image-pickup element 53.

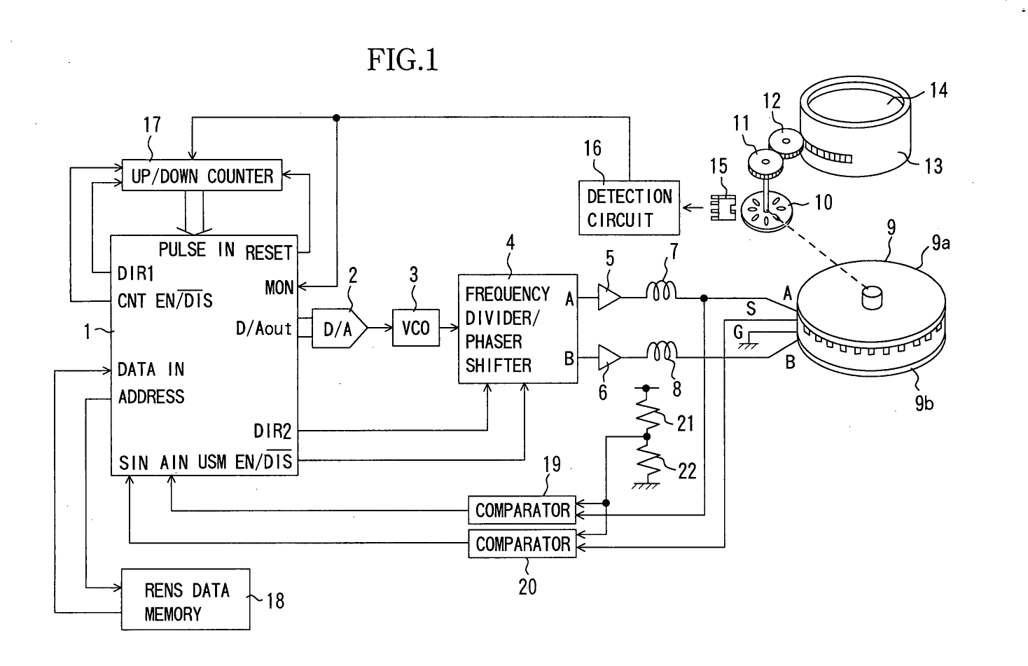

FIG. 1 is a block diagram showing the structure of a vibration type motor 9 and a control device therefor, which are mounted to the camera system.

In FIG. 1, reference numeral 1 denotes a microcomputer serving as a controller, which controls the various operations of the camera system, in addition to the control of the vibration type motor 9 (in the present embodiment, this is the driving control of the focusing lens 52 during focusing control). Reference numeral 2 denotes a D/A converter, which converts a digital output signal (D/Aout) of the microcomputer 1 into an analog output signal. Reference numeral 3 denotes a voltage-controlled oscillator (also referred to as “VCO” below), which outputs a periodic voltage corresponding to an analog output voltage of the D/A converter 2.

Reference numeral 4 denotes a frequency divider/phase shifter, which divides the frequency of the periodic voltage from the VCO 3 and outputs rectangular signals A and B having a phase difference of n/2. Reference numerals 5 and 6 denote power amplifiers that amplify the periodic voltage from the frequency divider/phase shifter 4 to a voltage and current value which can drive the vibration type motor 9. Reference numerals 7 and 8 denote matching coils. The two periodic signals from the power amplifiers 5 and 6 are supplied to the vibration type motor 9 via those matching coils 7 and 8 respectively.

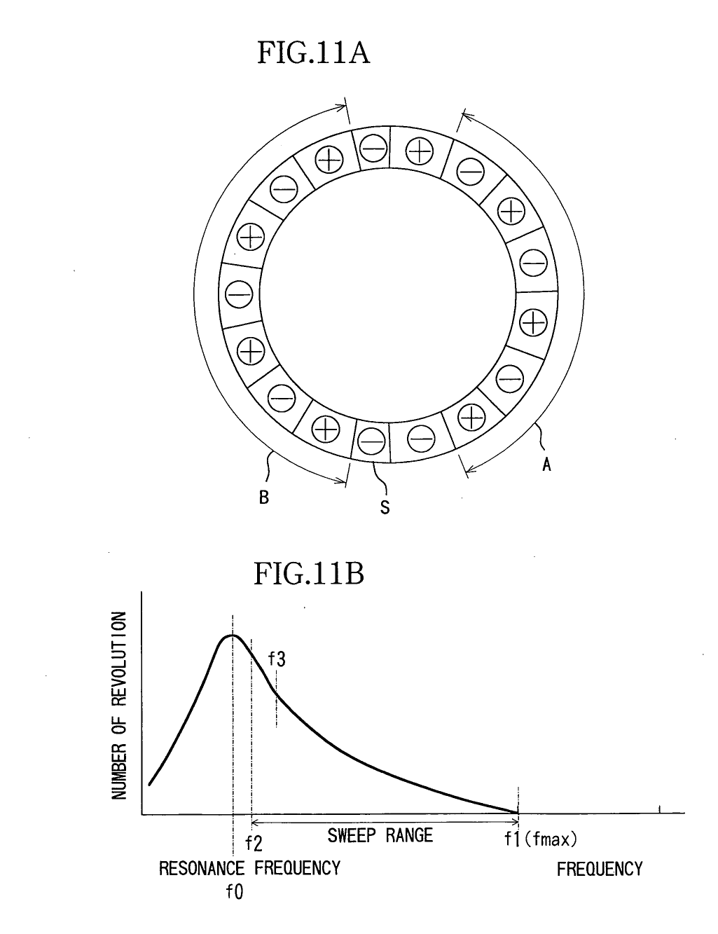

In the vibration type motor 9, reference numeral 9b denotes a circular ring-shaped stator (vibration member), and reference numeral 9a denotes a rotor (contact member) contacting a driving surface of the stator 9b. As shown in FIG. 11A, an A-phase piezoelectric element group A, a B-phase piezoelectric element group B, and a sensor-phase piezoelectric element S, are attached to the surface of the stator 9b that is opposite the driving surface. Their phases and polarities (+, −) are as shown in FIG. 11A. The sensor-phase piezoelectric element S is arranged at a position whose phase is shifted 45° with respect to the piezoelectric element group B. These piezoelectric elements can be attached individually to the stator 9b, or they can be formed together by a polarization process.

When the above-described two periodic signals are applied to the piezoelectric element group A and the piezoelectric element group B, then a traveling vibration wave is formed in the driving surface of the stator 9b. Moreover, when a traveling vibration wave is formed in the stator 9b, then a periodic voltage in accordance with the state of the traveling vibration wave is output from the sensor-phase piezoelectric element S, and it is possible to detect the driving state of the vibration type motor 9 from this periodic voltage.

It should be noted that when the vibration type motor 9 is in a resonant state, then the phase relation between the voltage of the periodic signal applied to the A-phase piezoelectric element group A and the periodic voltage output from the sensor-phase piezoelectric element S is in a specific relation that depends on the positional relation between the piezoelectric element group A and the sensor-phase piezoelectric element S. In the present embodiment, in the forward rotation state, a phase difference of 135° between the waveforms of the A-phase application signal and the S-phase output signal indicates the resonant state, whereas in the reverse rotation state, a phase difference of 45° indicates the resonant state. And the further away the driving state of the vibration type motor 9 is from the resonant state, the more the phase difference deviates from the above.

Moreover, by changing the frequency of the periodic signals applied to the piezoelectric element group A and the piezoelectric element group B (referred to as “driving frequency” below), it is possible to rotatively drive the vibration type motor 9 with the frequency—number of revolutions (speed) characteristics shown in the graph of FIG. 11B. In FIG. 11B, the frequency at which the highest motor speed can be attained is the resonance frequency f0, but in actual control, the frequency is controlled within a sweep range. The sweep range is a range between a sweep start frequency (first frequency) f1 that is equivalent to a frequency (fmax) at which the motor 9 starts to rotate and a sweep lower limit frequency (second frequency) f2 which is set to be higher by a predetermined margin than the resonance frequency f0.

In FIG. 1, reference numeral 10 denotes a pulse plate, which is a circular plate provided with a plurality of slits extending in radial directions from the rotation center, as shown in FIG. 1. The rotation from an output shaft of the vibration type motor 9 is transmitted via a gear 11 to the pulse plate 10. Moreover, the gear 11 meshes with a gear 12, which meshes with a circumferential gear portion of a lens barrel 13, which is part of the lens section 55 in FIG. 12.

Reference numeral 14 denotes a lens (the focusing lens 52 shown in FIG. 12), which is held by the lens barrel 13. Reference numeral 15 denotes a photo-interrupter, which generates a pulse signal by receiving (or not receiving) light that has passed through the slits in accordance with the rotation of the pulse plate 10.

Reference numeral 16 denotes a detection circuit which amplifies the low-power signal from the photo-interrupter 15 and converts it into a digital signal (pulse signal). Reference numeral 17 denotes an up/down counter, which counts the pulse signals generated due to the rotation of the pulse plate 10. By counting the pulse signals, it is possible to detect the drive amount of the lens barrel 13 (i.e. the focusing lens 52).

Reference numeral 18 denotes a lens data memory, in which the open F number and the focal length that are characteristic for the image-taking optical system as well as a speed table for driving the focusing lens 52 are stored.

Reference numerals 19 and 20 denote phase comparators, which shape the waveform applied to the A-phase and the waveform output from the S-phase such that it can be input into the microcomputer 1, by comparing the waveform applied to the A-phase and the waveform output from the S-phase with a reference voltage produced by waveform voltage-dividing resistors 21 and 22.

The following is an explanation of the terminals of the microcomputer 1. DIR1 is an output terminal whose output instructs the count direction of the up/down counter 17: “H” means up and “L” means down. PULSE IN is an input terminal for the count value of the up/down counter 17. MON is an input terminal for directly monitoring the output of the detection circuit 16. RESET is an output terminal whose output instructs a reset of the up/down counter 17. A reset is instructed by “H”

CNT EN/DIS is an output terminal for enabling or prohibiting the counting with the up/down counter 17: “H” allows counting and “L” prohibits counting. D/Aout is an output terminal for output to the D/A converter 2. DIR2 is an output terminal for instructing the frequency divider/phase shifter 4 to change the phase difference between the two periodic voltages applied to the vibration type motor 9 to 90° or 270°, in order to switch the rotation direction of the vibration type motor 9. USM EN/DIS is an output terminal for turning the output of the frequency divider/phase shifter 40N or OFF: “H” means ON and “L” means OFF. AIN and SIN are input terminals for the signals of the A-phase and S-phase shaped by the comparator 19 and the comparator 20, respectively.

ADDRESS is an output terminal for designating an address of the lens data memory 18, and designates which data in the lens data memory 18 are output. DATA IN is an input terminal for the data stored in the lens data memory 18 at the address that is specified by the signal from the ADDRESS terminal.

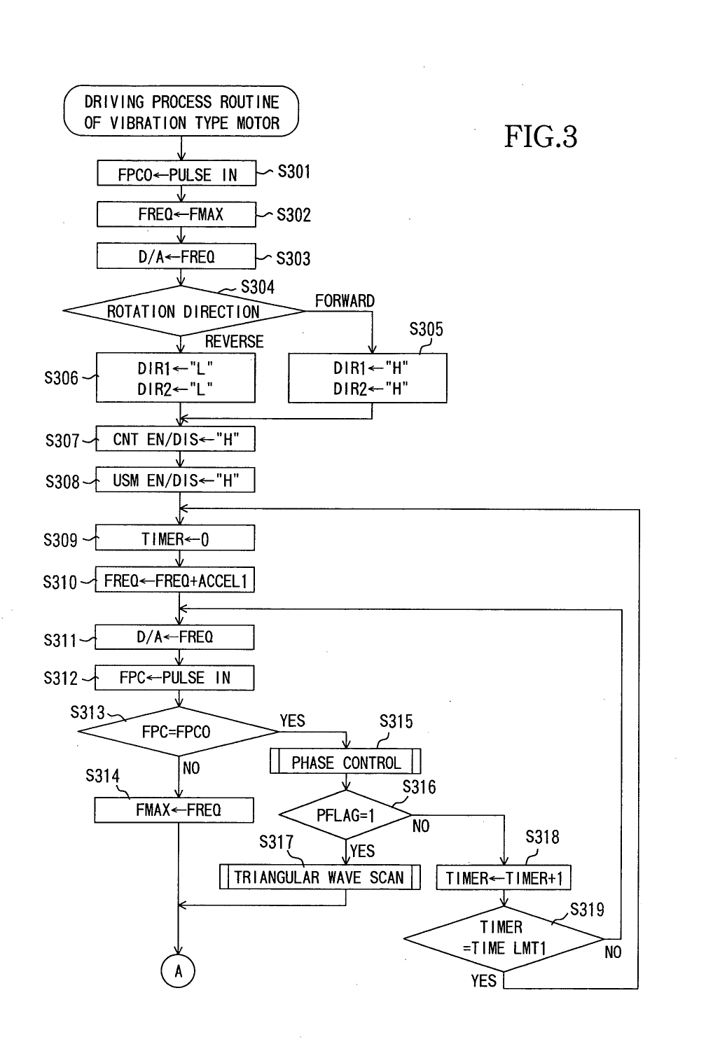

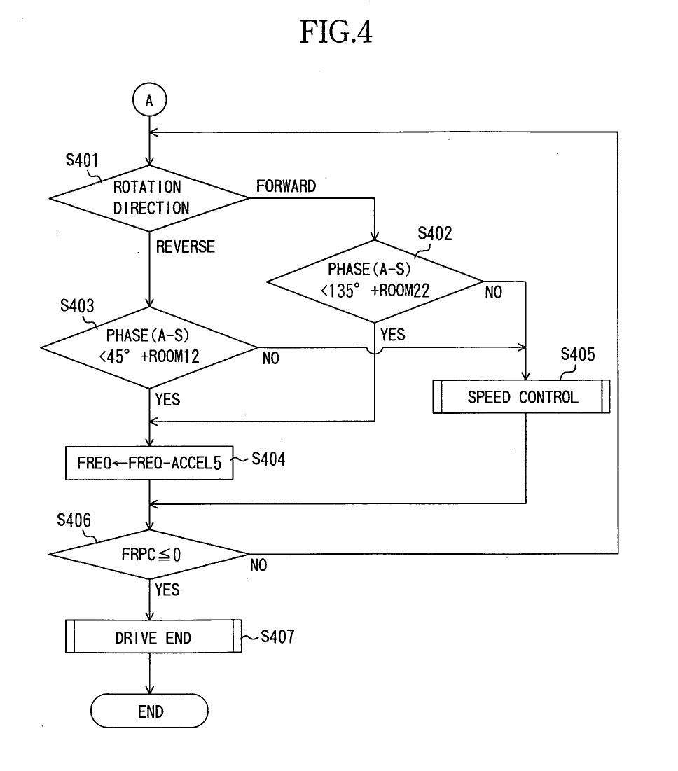

The following is an explanation of the control operation according to the present embodiment. FIGS. 3, 4, 5, 6, 7 and 8 are flowcharts showing the content of a program stored in a ROM (not shown in the drawings) incorporated in the microcomputer 1 in FIG. 1. The microcomputer 1 executes the control operation in accordance with these flowcharts. It should be noted that the flows in FIGS. 3 and 4 are connected to one another at the portions marked by the circled A's.

When the driving control routine (in the present embodiment, the driving control routine of the focusing lens 52) of the vibration type motor 9 is started, first, Step 301 (in the figures, steps are abbreviated to “S”) in FIG. 3 is executed.

At Step 301, the microcomputer 1 receives the initial value of the up/down counter 17 with the terminal PULSE IN, and stores this initial value in the variable FPC0.

Next, at Step 302, the value of the variable FMAX is transferred to the variable FREQ. The variable FMAX is the initial frequency determined based on the driving frequency when the vibration type motor 9 was driven the previous time. If the vibration type motor 9 was normally stopped the previous time, then the driving frequency at which it was confirmed to start moving is stored in a memory, such as a RAM not shown in the drawings. Moreover, the value that is actually output at the terminal D/Aout is directly stored as the variables FMAX and FREQ, and the smaller this value is, the higher is the driving frequency.

Next, at Step 303, the value of FREQ, which was set at Step 302, is output to the terminal D/Aout. Thus, the D/A converter 2 converts the digital voltage value output by the terminal D/Aout into an analog voltage, and outputs this analog voltage to the VCO 3. The VCO 3 converts the voltage that was output by the D/A converter 2 into a frequency and outputs this frequency to the frequency divider/phase shifter 4.

At Step 304, the rotation direction of the motor 9 is discriminated. If the motor 9 rotates forward, then the procedure advances to Step 305, and if the motor 9 rotates in reverse, then the procedure advances to Step 306.

At Step 305, the rotation direction is forward, so that “H” is output at the terminal DIR1, and the count direction of the up/down counter 17 is set to the upward (incrementing) direction. Moreover, “H” is output at the terminal DIR2, and the phase difference between the signal A (the signal applied to the piezoelectric element group A) and the signal B (the signal applied to the piezoelectric element group B) that are output by the frequency divider/phase shifter 4 is set to 90°, and then the procedure advances to Step 307.

At Step 306, the rotation direction is reverse, so that “L” is output at the terminal DIR1, and the count direction of the up/down counter 17 is set to the downward (decrementing) direction. Moreover, “L” is output at the terminal DIR2, and the phase difference between the signal A and the signal B that are output by the frequency divider/phase shifter 4 is set to 270°, and then the procedure advances to Step 307.

At Step 307, “H” is output at the terminal CNT EN/DIS, thus enabling counting with the up/down counter 17.

At Step 308, “H” is output at the terminal USM EN/DIS, thus enabling the output signals A and B of the frequency divider/phase shifter 4. Thus, the frequency divider/phase shifter 4 outputs signals A and B that have a frequency corresponding to the voltage output by the VCO 3 and a phase difference corresponding to the level of the signal output from the terminal DIR2. The output signals A and B are amplified by the power amplifiers 5 and 6, and are respectively applied to the piezoelectric element groups A and B via the matching coils 7 and 8. Thus, the vibration type motor 9 is about to start rotating.

Next, at Step 309, “0” is stored in the variable TIMER. The variable TIMER is a counter for measuring a predetermined time which is used for lowering the frequency by a predetermined frequency every time that this predetermined time has passed without detecting rotation of the motor 9.

Next, at Step 310, a constant ACCEL1 is added to the variable FREQ, and the result of this addition is stored in the variable FREQ.

Next, at Step 311, the value of the variable FREQ is output at the terminal D/Aout.

Then, at Step 312, the counter value is received from the up/down counter 17 and stored in the variable FPC.

Next, at Step 313, the variables FPC and FPC0 are compared. If FPC and FPC0 are equal, then the procedure advances to Step 315, and if they are not equal, then the procedure advances to Step 314. That is to say, if the detection circuit 16 detects a rotation of the pulse plate 10, and the up/down counter 17 performs a count operation, then FPC≠FPC0, so that the procedure advances to Step 314. And when no rotation of the pulse plate 10 has been detected, then FPC=FPC0, so that the procedure advances to Step 315.

At Step 314, a rotation of the pulse plate 10 has been detected at Step 313, so that the frequency FREQ at that time is stored in the variable FMAX.

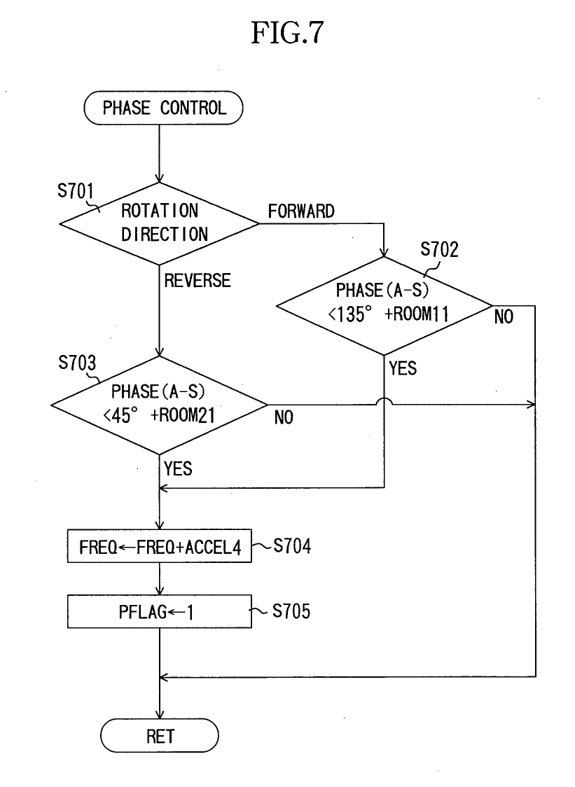

At Step 315, a phase control (explained below in detail with reference to FIG. 7) is carried out, and it is ensured that the frequency does not become lower than the resonance frequency when lowering the frequency at constant time intervals. Then, the procedure advances to Step 316.

At Step 316, the state of a flag PFLAG, indicating that the phase difference has become close to the resonance state in the phase control subroutine of Step 315, is discriminated. If PFLAG is 1, that is, if the driving frequency has reached a lower limit frequency f2 and the frequency should not be lowered any further, then the procedure advances to Step 317. If PFLAG is 0, that is, if the driving frequency has not yet reached the lower limit frequency f2, then the procedure advances to Step 318.

At Step 317, a later-described triangular wave scan of the driving frequency is performed.

At Step 318, the variable TIMER is incremented.

At Step 319, it is discriminated whether TIMER is equal to the predetermined time TIME LMT1. If yes, then the procedure advances to Step 309, and if no, then the procedure advances to Step 311. Here, a process for lowering the driving frequency at every predetermined time (every time TIMER=TIMER LMT1 at Step 319) is performed through Step 310. This is done so that the driving frequency is not lowered too rapidly. Consequently, when the procedure branches to NO at Step 319, then it is not yet necessary to lower the driving frequency, so that the procedure advances to Step 311, and the driving frequency stays the same until the predetermined time has elapsed.

Next, at Step 401 in FIG. 4, the rotation direction of the motor 9 is discriminated. If the motor 9 rotates forward, then the procedure advances to Step 402, and if the motor 9 rotates in reverse, then the procedure advances to Step 403.

At Step 402, it is discriminated whether the phase difference between the A-phase and the S-phase which have been received at the terminal AIN and the terminal SIN is smaller than “135°+phase margin ROOM22”. If yes, then the procedure advances to Step 404, and if no, then the procedure advances to Step 405.

At Step 403, it is discriminated whether the phase difference between the A-phase and the S-phase which have been received at the terminal AIN and the terminal SIN is smaller than “45°+phase margin ROOM12”. If yes, then the procedure advances to Step 404, and if no, then the procedure advances to Step 405.

At Step 404, the phase difference is further advancing from the phase difference of the resonance state so that the frequency is returned to a frequency that is higher by the predetermined frequency value ACCEL5.

At Step 405, the phase difference has a margin to the phase difference in the resonance state, so that speed control is performed.

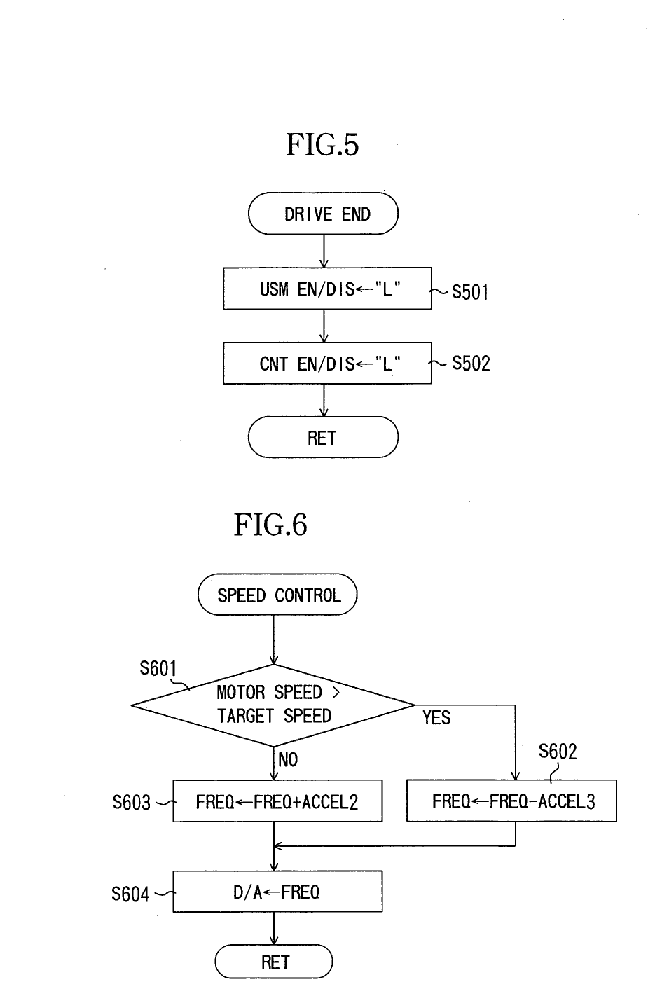

At Step 406, it is discriminated whether or not the variable FRPC indicating the remaining drive amount of the motor 9 (the focusing lens 52) is smaller than or equal to zero. Here, the remaining drive amount is the drive amount that remains to the in-focus position of the focusing lens 52 detected by using the phase difference detection method, or the drive amount that remains when driving the focusing lens 52 by predetermined differential amounts in order to find the in-focus position by the contrast detection method. If FRPC>0, then a drive amount still remains, so that the procedure returns to Step 401, whereas if FRPC≦0, then the remaining drive amount is zero (the driving to the target drive amount has been finished), or the drive amount is larger than the target drive amount, so that the procedure advances to Step 407. At Step 407, the procedure advances to the end subroutine of the driving process shown in FIG. 5.

In the driving process end subroutine of FIG. 5, at Step 501, the microcomputer 1 outputs “L” at the terminal USM EN/DIS, disabling the output signals A and B of the frequency divider/phase shifter 4. Thus, the driving of the motor 9 is stopped.

Next, at Step 502, “L” is output at the terminal CNT EN/DIS, and counting with the up/down counter 17 is disabled.

FIG. 6 shows the speed control subroutine, which is carried out at Step 405 in FIG. 4; starting with Step 601.

At Step 601, the actual driving (rotation) speed of the motor 9 is compared with the target speed which has been stored beforehand in the ROM based on such information as the remaining drive amount. If the actual driving speed is faster than the target speed, then the procedure advances to Step 602, and if it is slower then the procedure advances to Step 603.

At Step 602, the actual driving speed is faster, so that a value obtained by subtracting a constant ACCEL3 from the variable FREQ is stored in the variable FREQ, and after increasing the frequency by a frequency increment corresponding to the constant ACCEL3, the procedure advances to Step 604.

At Step 603, the actual driving speed is slower, so that a value obtained by adding a constant ACCEL2 to the variable FREQ is stored in the variable FREQ, and after decreasing the frequency by a frequency increment corresponding to the constant ACCEL2, the procedure advances to Step 604.

At Step 604, the value of the variable FREQ is output at the terminal D/Aout.

FIG. 7 shows a subroutine of the phase control that is performed at Step 315 in FIG. 3 until the motor 9 has started.

At Step 701, the microcomputer 1 discriminates the rotation direction of the motor 9. If the motor 9 rotates forward, then the procedure advances to Step 702, and if the motor 9 rotates in reverse, then the procedure advances to Step 703.

At Step 702, it is discriminated whether the phase difference between the A-phase application signal and the S-phase output signal, which have been received at the terminal AIN and the terminal SIN, is smaller than “135°+phase margin ROOM11”. If yes, then the procedure advances to Step 704, and if no, then the procedure returns.

At Step 703, it is discriminated whether the phase difference between the A-phase application signal and the S-phase output signal is smaller than “45°+phase margin ROOM21”. If yes, then the procedure advances to Step 704, and if no, then the procedure returns.

At Step 704, the phase difference is further advancing from the resonance state, so that the driving frequency is returned to a frequency that is higher by the predetermined frequency value ACCEL4.

At Step 705, the phase difference has become close to the resonance state, so that also the driving frequency has reached the above-mentioned lower limit frequency, and the flag PFLAG is set to 1.

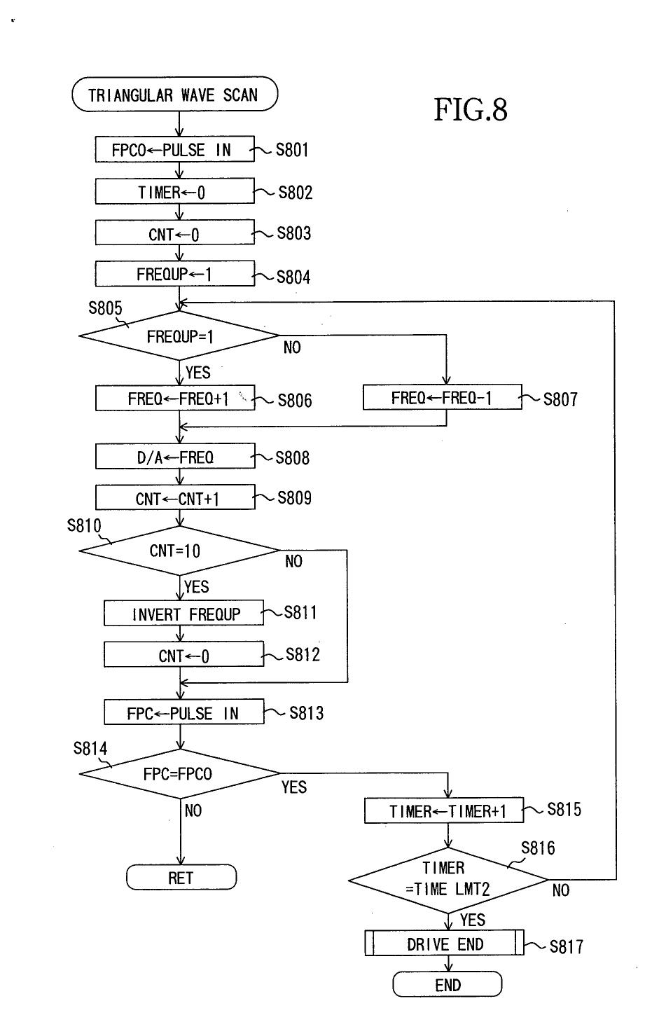

FIG. 8 shows the subroutine for the triangular wave scan of the driving frequency that is performed at Step 317 in FIG. 3.

At Step 801, the counter value of the up/down counter 17 at the start of the triangular wave scan is received at the terminal PULSE IN, and stored in the variable FPC0.

Then, at Step 802, 0 is stored in the variable TIMER. This variable TIMER is used for providing a time limit for the triangular wave scan process.

Next, at Step 803, 0 is stored in the variable CNT. This variable CNT is used as a counter for forming the triangular waveform for the triangular wave scan, and the frequency is repeatedly increased and decreased for ten counts each.

Then, at Step 804, the flag FREQUP is set to 1. This flag FREQUP is used to form the triangular waveform of the triangular wave scan.

Then, at Step 805, the state of the flag FREQUP is discriminated. If the state of the flag FREQUP is 1, then the procedure advances to Step 806, and if it is 0, then the procedure advances to Step 807.

At Step 807, the variable FREQ is decremented, and the driving frequency is shifted by one step towards the higher frequency side so that the driving frequency becomes a third frequency f3 that is higher than the afore-mentioned lower limit frequency f2, lower than the sweep start frequency f1, and moreover closer to the lower limit frequency f2 than the sweep start frequency f1. At Step 806, on the other hand, the variable FREQ is incremented, and the driving frequency is shifted by one step towards the lower frequency side so that the driving frequency becomes the original lower limit frequency f2.

Next, at Step 808, the variable FREQ is output at the terminal D/Aout.

Next, at Step 809, the variable CNT is incremented.

Moreover, at Step 810, it is discriminated whether the variable CNT has reached 10. If 10 has been reached, then the procedure advances to Step 811, and if 10 has not yet been reached, then the procedure advances to Step 813.

Next, at Step 811, since the variable CNT has reached 10 at Step 810, the flag FREQUP is inverted in order to switch increase and decrease of the driving frequency. Then, the procedure advances to Step 812.

At Step 812, the variable CNT is reset to 0, and then the procedure advances to Step 813.

At Step 813, the counter value is received from the up/down counter 17 and stored in the variable FPC.

Next, at Step 814, the variables FPC and FPC0 are compared. If they are equal, the procedure advances to Step 815, and if they are not equal, the procedure returns to Step 401 in FIG. 4. That is to say, if the detection circuit 16 detects a rotation of the pulse plate 10 and the up/down counter 17 has performed a count operation, then FPC≠FPC0, so that the procedure advances to Step 401 and the driving is performed by the target drive amount while performing speed control. If no rotation of the pulse plate 10 is detected, then FPC=FPC0, so that the procedure advances to Step 815.

At Step 815, the variable TIMER is incremented.

At Step 816, it is discriminated whether TIMER is equal to the predetermined time TIME LMT2. If yes, then the procedure advances to Step 817. If no, then the procedure advances to Step 805 and the next triangular wave scan process is performed.

At Step 817, the time of the triangular wave scan process has reached the time limit, so that the end routine of the drive process shown in FIG. 5 is performed.

In Steps 301 to 309 of the above-described operation, the initial settings for starting the motor are performed, the initial state of the up/down counter 17 is confirmed, the scan start frequency is output, the rotation direction is discriminated and set, and the start-up process of the motor 9 is initiated.

In Steps 310 to 319, it is confirmed whether the motor 9 has been started or not and a frequency scan is performed. In the frequency scan, the frequency is decreased by a predetermined amount every time that a predetermined time TIME_LMT1 has elapsed. If the phase difference becomes close to the resonance state (the lower limit frequency f2 is reached) before it has been confirmed that the motor has started, then the triangular wave scan routine is performed.

At Steps 401 to 406, the phase control and the speed control of the motor 9 are performed. First, the phase signal is checked, and if the phase difference between the A-phase application signal and the S-phase output signal is further advancing from the resonant state, then the drive frequency is increased by the predetermined value ACCEL5, and it is prevented that the motor 9 suddenly stops. If no phase control is performed, then speed control is performed. That is to say, if the actual driving speed is faster than the target speed, then the driving frequency is increased by the predetermined value ACCEL3, and if it is slower than the target speed, then the driving frequency is decreased by the predetermined value ACCEL2.

According to the properties of the vibration type motor 9, when the driving frequency is lowered below the lower limit frequency, which is a driving frequency near the maximum speed, then a sudden decrease in speed may result, so that the driving frequency near the maximum speed should not be changed too rapidly. Consequently, the predetermined values ACCEL2 and ACCEL3 are set to small values.

Steps 801 to 817 are a triangular wave scan routine performed when starting of the motor 9 cannot be confirmed and the phase difference has become close to the resonant state. Here, a triangular wave scan of the driving frequency is performed with a predetermined period. That is to say, the driving frequency is periodically increased and decreased between the lower limit frequency, which is the second frequency, and a third frequency which is one step higher than the lower limit frequency. However, there is a limit to the time in which this triangular wave scan is performed, and when the time limit comes, the triangular wave scan and the driving process are terminated. Also when starting of the motor 9 is confirmed, the procedure advances to Step 401 and ordinary processing is resumed.

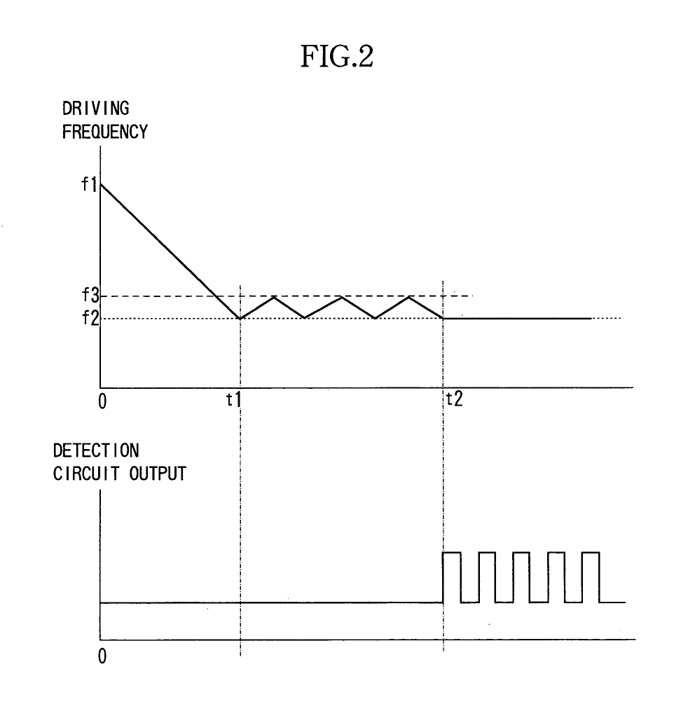

FIG. 2 is a timing chart showing the relation between the frequency adjustment and the detection result of the motor rotation with the detection circuit 16 in the present embodiment.

First, the motor driving process begins and the driving frequency is lowered. Then, after the driving frequency has reached the afore-mentioned lower limit frequency f2 (at the time t1), during a time in which no rotation of the motor 9 can be detected (time t1-t2), for example because the movement of a driven portion such as the focusing lens 52 or the lens barrel 13 is manually inhibited by the user or because the focusing lens 52 has been thrust against the infinity end or the close-range end (mechanical end) of its movable range, a triangular wave scan is commenced without fixing the driving frequency, in order to avoid squeaking of the vibration type motor 9. This timing chart shows the case that a rotation of the motor 9 can be detected at the time t2. In this case, the triangular wave scan is terminated, and the ordinary speed control is resumed.

As explained above, with this embodiment, while the motor 9 cannot be started for example because an external force is exerted on a driven member that is driven by the motor 9, the driving frequency is not held constant, but a triangular wave scan (periodic or continuous increase and decrease) is performed, and generation of a squeaking noise from the motor 9 can be suppressed while sustaining the torque of the motor 9.

Moreover, by periodically changing the frequency of the periodic signal, it is possible to quickly assume the desired driving state by detecting when the blocking of the motor is removed and driving has become possible.

Embodiment 2

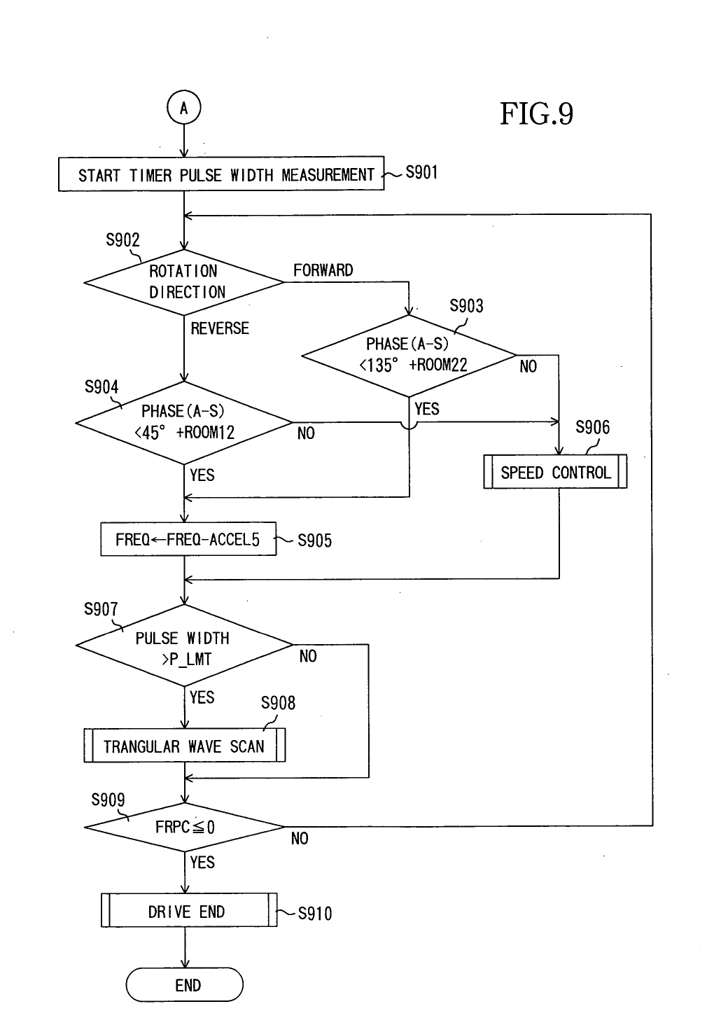

FIG. 9 is a flowchart of a control program of a vibration type motor according to Embodiment 2 of the present invention. The structure of the camera system and the vibration type motor to which the present embodiment is applied is the same as the structure explained with FIG. 1 in Embodiment 1, so that also the present embodiment is explained using the same reference numerals. Moreover, the control program for the camera system of the present embodiment is largely the same as the program explained with the flowchart shown in FIGS. 3 to 8 in Embodiment 1, and the following explanations focus mainly on the portions that are different.

FIG. 9 shows the processing after the starting of the motor 9 has been confirmed until the driving by the target drive amount has been terminated. This corresponds to the flowchart shown in FIG. 4 in Embodiment 1, but in the present embodiment, the processing of Step 901, Step 907 and Step 908 has been added to the flowchart of FIG. 4.

At Step 901, the microcomputer 1 starts a timer for measuring the pulse width of the pulse signal that is output from the photo-interceptor 15 due to rotation of the pulse plate 10.

Next, at Step 902, the rotation direction of the motor 9 is discriminated. If the motor 9 rotates forward, then the procedure advances to Step 903, and if the motor 9 rotates in reverse, then the procedure advances to Step 904.

At Step 903, it is discriminated whether the phase difference between the A-phase application signal and the S-phase output signal which have been received at the terminal AIN and the terminal SIN is smaller than “135°+phase margin ROOM22”. If yes, then the procedure advances to Step 905, and if no, then the procedure advances to Step 906.

At Step 904, it is discriminated whether the phase difference between the A-phase application signal and the S-phase output signal which have been received at the terminal AIN and the terminal SIN is smaller than “45°+phase margin ROOM12”. If yes, then the procedure advances to Step 905, and if no, then the procedure advances to Step 906.

At Step 905, the phase difference is further advancing from the phase difference of the resonance state so that the driving frequency is returned to a frequency that is higher by the predetermined frequency value ACCEL5.

At Step 906, the phase difference has a margin to the resonance state, so that the speed control explained with reference to FIG. 6 in Embodiment 1 is performed.

At Step 907, the pulse width of the pulse signal generated by the rotation of the pulse plate 10 is measured using the above-mentioned timer, and it is discriminated whether or not this pulse width is larger than a constant P_LMT. If the pulse width is larger than P_LMT, then the procedure advances to Step 908, and if the pulse width is smaller than P_LMT, then the procedure advances to Step 909. The constant P_LMT is a threshold value that is used to detect when the rotation of the motor 9 has stopped, for example because a driven portion such as the focusing lens 52 or the lens barrel 13 has been manually stopped during driving of the motor 9 or because the focusing lens 52 has been thrust against the mechanical end of the infinity end or the close-range end. The constant P_LMT is set to for example 50 msec.

At Step 908, it was determined at Step 907 that the pulse width is larger than P_LMT and the focusing lens 52 has been stopped during driving of the motor 9, so that the triangular wave scan described with reference to FIG. 8 in Embodiment 1 is performed in order to avoid squeaking of the motor 9.

At Step 909, it is determined whether or not the constant FRPC is 0 or lower. If FRPC≦0, that is, if the driving by the target driving amount has been terminated or an overrun has occurred, then the procedure advances to Step 910, and if FRPC>0, that is, if there is still a remaining drive amount, then the procedure advances to Step 902.

At Step 910, the driving end process described with reference to FIG. 5 in Embodiment 1 is carried out.

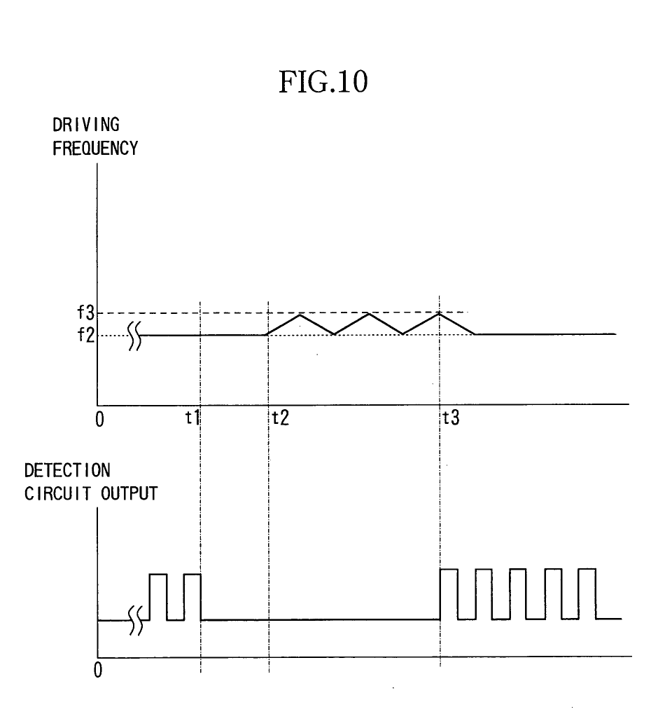

FIG. 10 is a timing chart showing the relation between the frequency adjustment and the detection result of the rotation of the motor 9 in the present embodiment.

At the time interval 0-t1, a rotation of the motor 9 has already been detected. In this situation, when the pulse width (t2−t1) of the pulse signal from the photo-interrupter 15 becomes larger than P_LMT (time t2), for example due to a driven member such as the focusing lens 52 being manually stopped, then the triangular wave scan is begun. Then, at the time t3, rotation of the motor 9 is detected again, the triangular wave scan is terminated, and ordinary speed control is resumed.

As explained above, with the present embodiment, if the rotation of the motor 9 is stopped due to an external force or the like during driving of the motor 9, then generation of a squeaking noise from the motor 9 can be suppressed while sustaining the torque of the motor 9, by performing a triangular wave scan without fixing the driving frequency to a constant frequency.

Moreover, by periodically changing the frequency of the periodic signal, it is possible to quickly attain the desired driving state by detecting when the blocking of the motor is removed and driving has become possible.

It should be noted that in the foregoing embodiments, examples were described in which a triangular wave scan of the driving frequency is performed while the motor cannot be started, but the present invention is not limited to this. That is to say, as long as it is a method by which the driving frequency is not fixed to a constant frequency (but continuously changed), it is also possible to perform a scan of increasing and decreasing the frequency along a sine wave form, or to change the frequency randomly between the lower limit frequency f2 and the third frequency f3 as shown in FIG. 13, or to change the amplitude.

Moreover, the foregoing embodiments explained the control of a ring-type vibration motor, but the present invention can also be applied to the control of so-called rod-type or other types of vibration motors.

Furthermore, the foregoing embodiments were explained for camera systems using the vibration type motor as the driving source for the focusing lens, but the present invention can also be applied to cases where the vibration type motor is used as the driving source for other lenses (such as the zooming lens), or to apparatuses other than camera systems, which use a vibration type motor as a driving source-(for example an image formation apparatus such as a copying machine or the like).

With the foregoing embodiments as explained above, in a case where a vibration type actuator is not being driven, due to the driving being inhibited by an external force or the like, even though the vibration type actuator is in a state in which a periodic signal having a second frequency is applied and the vibration type actuator should be driven, the frequency of the periodic signal is continuously (or periodically) changed between a second frequency and a third frequency, so that it is avoided that the vibration state of the vibration member becomes instable, and so-called squeaking (abnormal noise) is suppressed.

Furthermore, the third frequency is lower than the first frequency, so that squeaking can be suppressed while sustaining the generation of torque. In particular, by setting the third frequency to a frequency that is closer to the second frequency than to the first frequency, changes in the torque can be kept small.

Furthermore, by changing the frequency of the periodic signal periodically, it is possible to assume the desired driving state when blocking of the driving has been removed more quickly than in the case that the frequency of the periodic signal is changed randomly.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

This application claims priority from Japanese Patent Application No. 2003-309207 filed on Sep. 1, 2003, which is hereby incorporated by reference herein.

1. A control device for a vibration type actuator exciting vibrations in a vibration member by applying a periodic signal to an electro-mechanical energy conversion element, and driving the vibration member relative to a contact member contacting the vibration member, the control device comprising:
a controller controlling a frequency of the periodic signal between a first frequency and a second frequency which is lower than the first frequency; and
a detector detecting driving of the vibration type actuator;
wherein, in a case where driving of the vibration type actuator is not detected by the detector even when the frequency of the periodic signal is set to the second frequency, the controller continuously changes the frequency of the periodic signal between the second frequency and a third frequency that is lower than the first frequency until driving of the vibration type actuator is detected.

2. The control device according to claim 1,
wherein the controller periodically changes the frequency of the periodic signal between the second frequency and the third frequency until driving of the vibration type actuator is detected.

3. The control device according to claim 1,
wherein the third frequency is a frequency that is closer to the second frequency than to the first frequency.

4. The control device according to claim 1,
wherein the second frequency is a lower limit frequency that can be set by the controller within a range of frequencies that are higher than a resonance frequency of the vibration type actuator.

5. A device comprising:
a vibration type actuator serving as a driving source;
the control device according to claim 1; and
a driven member driven by the vibration type actuator.

6. An optical equipment comprising:
a vibration type actuator serving as a driving source;
the control device according to claim 1;
a driven member driven by the vibration type actuator.

7. A control method for controlling a vibration type actuator exciting vibrations in a vibration member by applying a periodic signal to an electromechanical energy conversion element, and driving the vibration member relative to a contact member contacting the vibration member, the control method comprising:
a first step of controlling a frequency of the periodic signal between a first frequency and a second frequency which is lower than the first frequency; and
a second step of detecting driving of the vibration type actuator; and
a third step of continuously changing the frequency of the periodic signal between the second frequency and a third frequency that is lower than the first frequency until driving of the vibration type actuator is detected, in a case where driving of the vibration type actuator is not detected even when the frequency of the periodic signal is set to the second frequency.

8. A control program operated on a computer, the control program controlling a vibration type actuator exciting vibrations in a vibration member by applying a periodic signal to an electro-mechanical energy conversion element, and driving the vibration member relative to a contact member contacting the vibration member, and the control program comprising:
a first step of controlling a frequency of the periodic signal between a first frequency and a second frequency which is lower than the first frequency; and
a second step of detecting driving of the vibration type actuator; and
a third step of continuously changing the frequency of the periodic signal between the second frequency and a third frequency that is lower than the first frequency until driving of the vibration type actuator is detected, in a case where driving of the vibration type actuator is not detected even when the frequency of the periodic signal is set to the second frequency.

9. A control device for a vibration type actuator exciting vibrations in a vibration member by applying a periodic signal to an electro-mechanical energy conversion element, and driving the vibration member relative to a contact member contacting the vibration member, the control device comprising:
a controller controlling a frequency of the periodic signal between a first frequency and a second frequency which is lower than the first frequency; and
a detector detecting driving of the vibration type actuator;
wherein, in a case where driving of the vibration type actuator is not detected by the detector even when the frequency of the periodic signal is set to a third frequency between the first and the second frequency, the controller repeatedly changes the frequency of the periodic signal between the third frequency and a fourth frequency.

10. The control device according to claim 9,
wherein the third frequency is the same as the second frequency, and the fourth frequency is higher than the third frequency.

11. The control device according to claim 9,
wherein the changing of the frequency of the periodic signal between the third frequency and the fourth frequency is stopped in response to detecting driving of the vibration type actuator.

12. A device comprising:
a vibration type actuator serving as a driving source;
the control device according to claim 9; and
a driven member driven by the vibration type actuator.

13. An optical equipment comprising:
a vibration type actuator serving as a driving source;
the control device according to claim 9; and
a driven member driven by the vibration type actuator.

14. A control method for controlling a vibration type actuator exciting vibrations in a vibration member by applying a periodic signal to an electro-mechanical energy conversion element, and driving the vibration member relative to a contact member contacting the vibration member, the control method comprising:
a first step of controlling a frequency of the periodic signal between a first frequency and a second frequency which is lower than the first frequency; and
a second step of detecting driving of the vibration type actuator; and
a third step of, in a case where driving of the vibration type actuator is not detected even when the frequency of the periodic signal is set to a third frequency between the first and the second frequency, repeatedly changing the frequency of the periodic signal between the third frequency and a fourth frequency.

15. A control program operated on a computer, the control program controlling a vibration type actuator exciting vibrations in a vibration member by applying a periodic signal to an electro-mechanical energy conversion element, and driving the vibration member relative to a contact member contacting the vibration member, and the control program comprising:
a first step of controlling a frequency of the periodic signal between a first frequency and a second frequency which is lower than the first frequency; and
a second step of detecting driving of the vibration type actuator; and
a third step of, in a case where driving of the vibration type actuator is not detected even when the frequency of the periodic signal is set to a third frequency between the first and the second frequency, repeatedly changing the frequency of the periodic signal between the third frequency and a fourth frequency.
